(19) United States
(12) Patent Application Publication
(10) Pub. No.: US 2016/0336925 A1
(43) Pub. Date: Nov. 17, 2016

(54) SCAN SEQUENTIAL ELEMENT DEVICE

(71) Applicant: COMMISSARIAT À L'ENERGIE ATOMIQUE ET AUX ENERGIES ALTERNATIVES, Paris (FR)

(72) Inventors: Valentin GHERMAN, PALAISEAU (FR); Samuel EVAIN, SACLAY (FR); Sébastien SARRAZIN, PARIS (FR)

(21) Appl. No.: 15/112,975

(22) PCT Filed: Jan. 27, 2015
(86) PCT No.: PCT/EP2015/051625

§ 371 Date: Jul. 20, 2016

(30) Foreign Application Priority Data
Jan. 30, 2014 (FR) 1450725

(51) Int. Cl. H03K 3/3562; G01R 31/3185

(52) U.S. Cl. CPC H03K 3/3562; G01R 31/318541

(57) ABSTRACT

A scan sequential element device for an integrated circuit receiving three input signals, at least one clock signal as input, and an output comprises: a system sequential element including an input controlled by a first input signal of the device, an input controlled by a second input signal of the device, and an input controlled by one of the clock signals received as input by the device, and a shadow sequential element including an input controlled by the third input signal of the device, an input controlled by the second input signal of the device, and an input controlled by one of said clock signals received as input by the device, the device being configured so the first input signal is propagated to the output of the device through the system sequential element when the second input signal is disabled, and the third input signal is propagated to the output of the device through the shadow sequential element and the system sequential element when the second input signal is enabled, the propagation of the third input signal of the shadow sequential element to the system sequential element being implemented asynchronously, i.e. decorrelated from the clock signals.

### TECHNICAL FIELD

The present invention relates in general to integrated circuits and in particular to a scan sequential element device (scan flip-flop for scan latch) having a low impact on performance.

### PRIOR ART

Digital circuits implemented on the basis of micro and nano technologies can be adversely affected by physical defects resulting from the manufacturing process. These defects may cause operating errors which may result in a failure of the systems in which these circuits are used.

The physical defects may generally be identified by means of production tests. The ability to detect these defects can be significantly increased by using scan sequential elements, e.g. scan flip-flops. With this type of flip-flop, the testing of a sequential circuit may be limited to testing its combinatorial part, thereby reducing the test vector generation effort. A property of this type is due to the fact that a scan flip-flop offers at least two operating modes: a capture mode (or normal mode) in which the data loaded into the flip-flops originate from the circuit, and a scan mode in which the scan flip-flops are interconnected to form one or more scan chains allowing the routing of the test vectors and the unloading of the responses from the circuit. During the testing of a circuit, the scan and capture modes are alternated in order to apply the test vectors to the circuit and to capture and retrieve the responses from the circuit.

Examples of scan flip-flops are described in “Storage Cells for Scan Designs”, M. Abramovici, M. A. Breuer, A. D. Friedman “Digital Systems Testing and Testable Design”, IEEE Press, 1990, section 9.5. A major disadvantage of these scan flip-flops is linked to their impact on the performance of the circuits.

Known approaches aimed at reducing the impact of scan flip-flops on latency are based on the architecture of the scan flip-flop, such as, for example, the solution described in the article entitled “Eliminating Performance Penalty of Scan”, O. Sinanoglu, “International Conference on VLSI Design”, 2012. As shown in FIG. 1, a solution of this type uses an additional flip-flop 10, referred to as a “shadow flip-flop”, in order to avoid the insertion of a multiplexer 12 in front of the system flip-flop 11 in order to allow the implementation of the scan and capture operating modes. However, this solution requires the insertion of an additional multiplexer 13 at the output of the system flip-flop 11, the effect of which is simply to transfer the impact of the scan from the input to the output of the system flip-flop.

A different solution for reducing the impact on latency is described in patent U.S. Pat. No. 7,310,755 B2. This solution aims to provide online monitoring of the circuits. However, it allows the insertion of the system flip-flop into a scan chain using a latch-type shadow flip-flop, referred to as a “shadow latch”. The shadow latch is coupled to the system flip-flop in such a way as to reduce the impact of the scan on the latency of the system flip-flop. This solution has a plurality of limitations in the case where it is used as a test solution, including:

the online activation of the shadow latch,

the fact that the functional input is connected to the shadow latch, thus introducing an increase in the latency of the circuit,

the presence of different clock signals for the system flip-flop and the shadow latch, and

the infrastructure which generates an “Error_L” signal, used for the online monitoring of the system.

Another disadvantage of the solution described in U.S. Pat. No. 7,310,755 B2 is linked to the fact that the multiplexer, controlled by the “Error_L” signal which allows the coupling between the system flip-flop and the shadow latch, can generate noise in scan mode.

### General Definition of the Invention

The invention improves the situation by proposing a scan sequential element device for an integrated circuit, the device receiving three respective input signals (D, SI, SE) and at least one clock signal CLK as input, and including an output Q. The device includes:

a system sequential element including an input controlled by a first input signal (D) of the device, an input controlled by a second input signal (SE) of the device, and an input controlled by one of the clock signals (CLK) received as input by the device, and

a shadow sequential element including an input controlled by the third input signal (SI) of the device, an input controlled by the second input signal (SE) of the device, and an input controlled by one of the clock signals (CLK) received as input by the device,

the device being configured in such a way that the first input signal (D) is propagated to the output (Q) of the device through the system sequential element when the second input signal (SE) is disabled, and the third input signal (SI) is propagated to the output (Q) of the device through the shadow sequential element and the system sequential element when the second input signal (SE) is enabled, the propagation of the third input signal (SI) of the shadow sequential element to the system sequential element being implemented asynchronously, i.e. decorrelated from the clock signals.

According to one characteristic of the invention, the shadow sequential element can be configured to be disconnected from the power supply when the second signal (SE) is disabled.

The shadow sequential element may include, in particular, at least one transistor connected to the third input controlled by the second signal (SE), said transistor being configured to disconnect the power supply of the shadow sequential element when the second input signal (SE) is disabled.

According to a different characteristic, the system sequential element may be a sequential element in the form of either a non-scan flip-flop or a latch, whereas the shadow sequential element may be a sequential element in the form of either a scan flip-flop, a non-scan flip-flop, or a latch.

The device can be connected at its input to an asynchronous reset signal resetting to the value logical 0 (“reset_n”) and/or to an asynchronous reset signal resetting to the value logical 1 (“set”), whereas the device is configured to form a scan flip-flop with asynchronous resetting to the value logical 0 and/or the value logical 1.

In one embodiment, the system sequential element includes a system master latch, a system slave latch and a logic gate, and the shadow sequential element includes a shadow latch receiving the third signal (SI) as input and being connected at its output to the output of the shadow sequential element. The logic gate receives the second signal (SE) as input, the output of the shadow sequential element and the asynchronous reset signal resetting to the value logical 0 (“reset_n”), and is connected at its output to the system master latch. The system master latch furthermore receives the first input signal (D) of the device and the second input signal (SE) of the device as input and is connected at its output to the system slave latch, the system slave latch being connected at its input to the system master latch and to the asynchronous reset signal resetting to logical 0 (“reset_n”) and being connected at its output to the output of the device (Q).

In a different embodiment, the system sequential element may include a system latch and a logic gate, whereas the shadow sequential element includes a shadow master latch receiving the third signal (SI) as input and a shadow slave latch connected at its output to the output of the shadow sequential element. The logic gate receives as input the second signal (SE), the output of the shadow sequential element and the asynchronous reset signal resetting to the value logical 0 (“reset_n”), and is connected at its output to the system latch, the system latch furthermore receiving the first input signal (D) of the device and the second input signal (SE) of the device as input and being connected at its output to the output of the device (Q).

In particular, the state of the system latch is reset asynchronously to the value logical 0 if the logic gate is enabled, whereas the system latch is reset synchronously or asynchronously to the value logical 1 if the logic gate is disabled and if the device is in scan mode, the device being in scan mode when the second signal (SE) is enabled.

The logic gate is enabled only if:

the asynchronous reset signal resetting to the value logical 0 (“reset_n”) is enabled, or

the device is in scan mode and the output of the shadow sequential element assumes the value logical 0.

In a different embodiment, the system sequential element includes a system master latch, a system slave latch and a logic gate, whereas the shadow sequential element includes a shadow latch receiving the third signal (SI) as input and is connected at its output to the output of the shadow sequential element. The logic gate receives as input the second signal (SE), the output of the shadow sequential element and the asynchronous reset signal resetting to logical 1 (“set”), and is connected at its output to the system master latch, the system master latch furthermore receiving the first input signal (D) of the device and the second input signal (SE) of the device as input and being connected at its output to the system slave latch, the system slave latch being connected at its input to the system latch and to the asynchronous reset signal resetting to logical 1 (“set”) and being connected at its output to the output of the device (Q).

As a variant, the system sequential element may include a system latch and a logic gate. The shadow sequential element includes a shadow master latch receiving the third signal (SI) as input and a shadow slave latch connected at its output to the output of the shadow sequential element. The logic gate receives the second signal (SE) as input, the output of the shadow sequential element and the asynchronous reset signal resetting to logical 1 (“set”), and is connected at its output to the system latch, the system latch furthermore receiving the first signal (D) and the second input signal of the device (SE) as input and being connected at its output to the output of the device (Q).

The state of the system latch is reset asynchronously to the value logical 1 if the logical is enabled, and the system latch is reset synchronously or asynchronously to the value logical 0 if the logic gate is disabled and the device is in scan mode, the device being in scan mode when the second signal (SE) is enabled.

In particular, the logic gate is enabled only if:

the asynchronous reset signal resetting to the value logical 1 (“set”) is enabled, or

the device is in scan mode and the output of the shadow sequential element assumes the value logical 1.

These different embodiments thus provide a new type of scan sequential element with a shadow sequential element which allows the impact of the scan on latency to be reduced. This solution eliminates all the limitations of the prior art while ensuring a very low impact on latency. Furthermore, the additional costs in terms of surface area and dissipated power outside testing are also substantially reduced.

### BRIEF DESCRIPTION OF THE DRAWINGS

Other characteristics and advantages of the invention will become evident from the description which follows and the attached figures, in which:

FIG. 1 shows a scan flip-flop architecture according to the prior art;

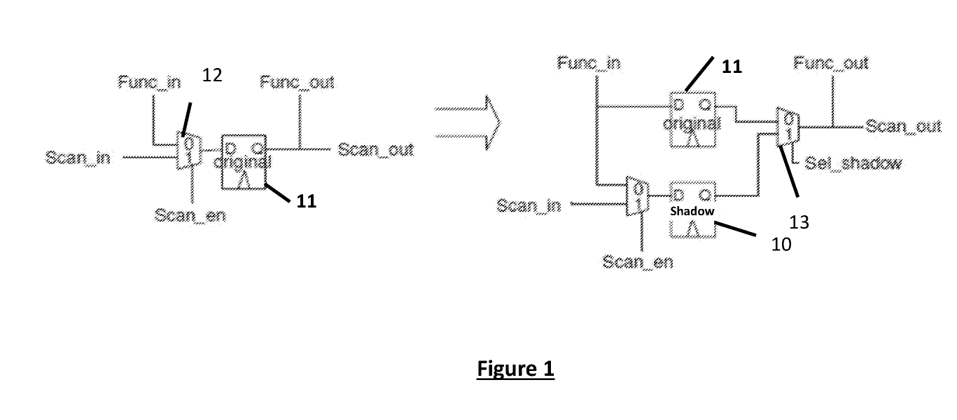

FIG. 2 shows the general structure of a scan sequential element device according to some embodiments of the invention;

FIG. 3 shows a scan flip-flop device with a shadow latch, a master/slave system flip-flop and a capability to reset the state of the system flip-flop asynchronously to logical 0 (“reset”), according to one embodiment of the invention;

FIG. 4 shows a scan latch device with a shadow flip-flop, a system latch and a capability to reset the state of the system latch asynchronously to logical 0 (“reset”);

FIG. 5 shows a scan flip-flop device with a shadow latch, a master/slave system flip-flop and a capability to reset the state of the system flip-flop asynchronously to logical 1 (“set”), according to a different embodiment; and

FIG. 6 shows a scan latch device with a shadow flip-flop, a system latch and a capability to reset the state of the system latch asynchronously to logical 1 (“set”);

### DETAILED DESCRIPTION

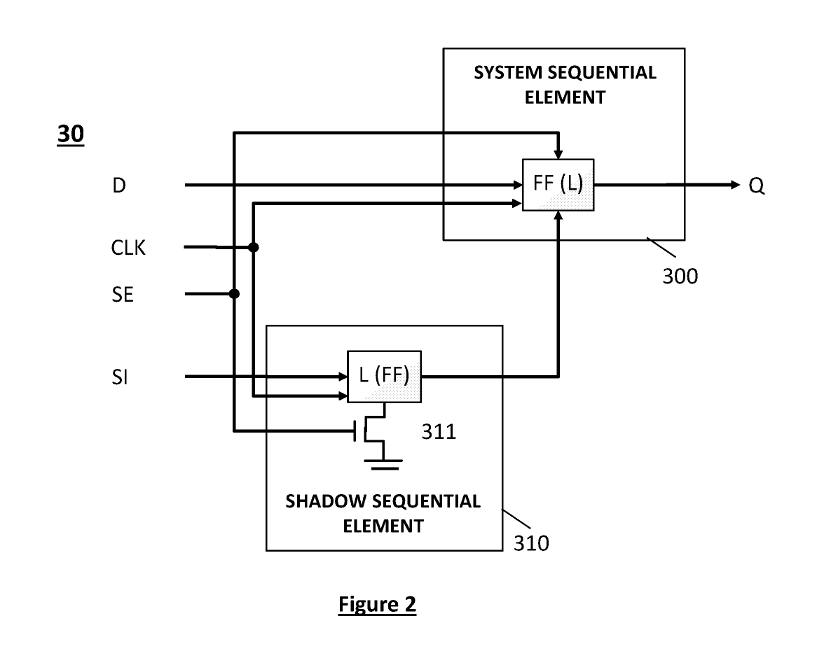

FIG. 2 shows a general view of the device 30 forming a sequential element for an integrated circuit which can be configured in capture mode or in scan mode, according to some embodiments of the invention. The device 30 includes a system sequential element 300 coupled with a shadow sequential element 310.

In particular, the shadow sequential element 310 may be a latch or a scan or non-scan flip-flop, whereas the system sequential element 300 may be a flip-flop (which may itself consist of a plurality of latches) or a latch.

In order to simplify the following description of the embodiments of the invention, the following parameters and components are defined:

Signal SE: The signal SE, also referred to as the “scan mode enable signal” (“SE” being the acronym for “Scan Enable”), refers to a signal which allows the scan and capture operating modes of a scan flip-flop to be defined. It will be assumed in the description below that the signal SE is enabled in scan mode, whereas the signal SE is disabled in capture mode; furthermore, although the invention is not limited to this embodiment, it is assumed in the description below that:
the signal SE is enabled when the signal SE assumes the value logical 1, and
the signal SE is disabled when the signal SE assumes the value logical 0.

A “latch” (designated below by the symbols L, ML, SL) refers to a sequential element which captures a datum as input, i.e. it becomes transparent, on a given level (high or low) of the clock signal. Although the clock signals are not shown explicitly in all of the figures, it is assumed below that the master latches denoted “ML” become transparent on the high level of the clock signal, whereas the slave latches denoted “SL” become transparent on the low level of the clock signal.

An asynchronous reset signal resetting to the value logical 0 (also denoted “logical 0”), also referred to below as “reset_n”, refers to a signal used to reset the state of a sequential element (e.g. a flip-flop or a latch) asynchronously to the value logical 0 when this signal is enabled. In the description below, it will be assumed by way of a non-limiting example that the signal “reset_n” is enabled if it assumes the value logical 0.

An asynchronous reset signal resetting to the logical value 1 (also denoted “logical 1”), also referred to as “set”, refers to a signal used to reset the state of a sequential element (e.g. a flip-flop or latch) asynchronously to the value logical 1 when this signal is enabled. In the description below, it will be assumed by way of a non-limiting example that the “set” signal is enabled if it assumes the value logical 1.

A sequential element is referred to as being a “system” sequential element when it is useful for the implementation of the functional specification of a circuit or system.

A sequential element referred to as a “shadow” sequential element is redundant in relation to the functional specification of a circuit or system, and is used to improve the parameters of the system, such as its testability.

As used in the present description, the terms “asynchronous” and “synchronous” characterize operations of resetting a sequential element to logical 0 or to logical 1. More precisely, an operation of this type is referred to as:

“asynchronous” if it is carried out in a manner that is decorrelated from the clock signal that is used to time the sequential element,

“synchronous” if it is carried out on a (high or low) level or on a (rising or falling) edge of the clock signal used to time the sequential element.

The device 30 supplies an output Q. It is controlled by at least one clock signal CLK and includes at least three inputs denoted D, SI and SE:
a first input D which is controlled by a first signal D,
a second input SE which is controlled by a second signal SE, and
a third input SI which is controlled by a third signal SI.

The system sequential element 300 includes at least:
one input connected to the input D of the device 30,
one input connected to the input SE of the device 30,
one input controlled by one of the clock signals CLK of the device 30,
one input connected to the output of the shadow sequential element 310, and
one input connected directly to the output Q of the device 30.

The shadow sequential element 310 includes at least:
one input connected to the second input SI of the device 30,
one input controlled by one of the clock signals CLK of the device 30, and
one output connected to an input of the system flip-flop 300.

According to one characteristic of the invention, the device 30 is configured in such a way as to propagate the signal D of the device 30 through the sequential element 300 to the output Q in capture mode (when the second input signal SE is disabled).

According to a different characteristic of the invention, in scan mode, the state of the shadow sequential element 310 is transmitted to the system sequential element 300. This property allows the propagation of the signal SI through the shadow sequential element 310 and the system sequential element 300, in scan mode (when the second input signal SE is enabled). The propagation of the input signal SI of the shadow sequential element 310 to the system sequential element 300 is implemented asynchronously, i.e. decorrelated from the clock signal CLK.

According to the configurations of the system and shadow sequential elements 300 and 310, the device 30 can also form a “scan flip-flop device” or a “scan latch device”.

In capture mode, the device 30 can be configured as a flip-flop or latch, depending on the type of the system sequential element 300, the data input of which is controlled by the signal D and the output controls the signal Q. The shadow sequential element 310 can be used in scan mode only, in order to configure the device 30 as a flip-flop, the data input of which is controlled by the signal SI and the output controls the signal Q.

In one preferred embodiment of the invention, the shadow sequential element 310 is a flip-flop, whereas the system sequential element 300 is a latch. Alternatively, the shadow sequential element 310 may be a latch when it is not used to perform the online monitoring, whereas the system sequential element 300 is a flip-flop.

In the embodiments where the shadow sequential element 310 is a latch, it may include logic gates allowing a pulse to be generated from one of the (rising or falling) edges of the clock signal CLK. Different methods for generating a pulse of this type can be used.

The system sequential element 300 may furthermore be controlled by asynchronous reset signals resetting to the value logical 0 (“reset_n”) and/or asynchronous reset signals resetting to the value logical 1 (“set”).

The system and shadow sequential elements 300 and 310 may share logic gates and transistors such as, for example, gates or transistors necessary for the inversion of the clock signal CLK.

A transistor 311, for example an n MOS transistor, can be used additionally to disconnect the power supply of the shadow sequential element 310 in capture mode. Additionally or alternatively, a p-type transistor can be used for the same purpose to disconnect the power supply of the shadow sequential element 310.

According to a different characteristic of the invention, the shadow sequential element 310 may be controlled by the same clock signal as the system sequential element 300.

In the embodiment where the system sequential element 300 is a system latch and where the shadow sequential element 310 is a shadow latch, optimum operation of the device in scan mode can be ensured by connecting the system and shadow latches in such a way that together they form a master-slave flip-flop (ML-SL), the data input of which is controlled by the third signal SI.

The device 30 avoids the insertion of a multiplexer in the path of the data which connects the input of the device which is controlled by the signal D to its output which controls the signal Q for the purpose of ensuring the implementation of the scan and capture modes. This results in a lower impact on the latency of the circuit or system in which the device 30 is inserted (the latency of a circuit defines the speed or the clock frequency at which the circuit can operate).

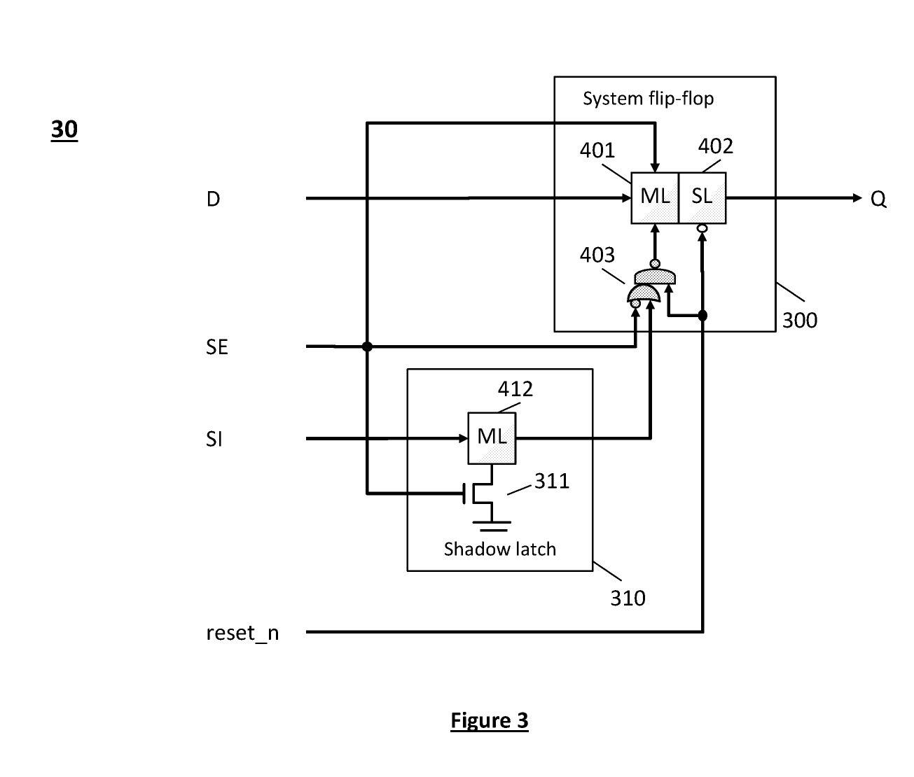

II should be noted that the clock signals of the sequential elements are not shown in FIGS. 3, 4, 5 and 6 in order to simplify the representation of these figures and for the sake of clarity, although they are used similarly to the embodiments described in relation to FIG. 2.

The device 30 may furthermore be connected at its input to a fourth signal “reset_n” allowing the state of the system sequential element and/or the shadow sequential element to be reset asynchronously to the value logical 0. The device 30 may furthermore be connected at its input to a fifth signal “set” allowing the system sequential element and/or the shadow sequential element to be reset asynchronously to the value logical 1.

FIG. 3 shows a device 30 capable of being used as a scan flip-flop with asynchronous resetting to the value logical 0 when the signal “reset_n” is enabled, according to some embodiments of the invention.

The system sequential element 300 shown in FIG. 3 includes a master latch 401 (also referred to as a “system master latch” and denoted “ML”), a slave latch 402 (also referred to as a “system slave latch” and denoted “SL”) and a logic gate 403. The shadow sequential element 310 shown includes a master latch (also referred to as a “shadow latch” or “shadow master latch” and denoted “ML”) 412 and a transistor 311 to disconnect the power supply of the latch ML 412 in capture mode.

The latch ML 401 becomes transparent on a given level of the clock signal, for example the high level, whereas the latch SL 402 becomes transparent on the opposite level, for example the low level. The association of two latches which become transparent on different levels of the same clock signal produces a flip-flop (denoted by the symbol “FF”), i.e. a sequential element which captures a datum as input on the (rising or falling) edge of the clock signal.

The latch ML 412 of the shadow sequential element includes an input controlled by the signal SI and an output connected to the output of the shadow sequential element 310.

The logic gate 403 includes:
an input controlled by the signal SE,
an input connected to the output of the shadow sequential element 310,
an input controlled by the signal “reset_n”, and
an output connected to the latch ML 401.

The latch ML 401 furthermore includes three inputs and one output, including:
an input connected to the output of the logic gate 403,
an input controlled by the signal D,
an input controlled by the signal SE, and
an output connected to the latch SL 402.

The latch SL 402 furthermore includes two inputs and one output, including:
an input controlled by the latch ML 401,
an input controlled by the signal “reset_n”,
an output which controls the signal Q.

The logic gate 403 is enabled, i.e. it has an impact on the state of the system sequential element 300, only if:
the asynchronous reset signal resetting to the value logical 0 “reset_n” is enabled, or
the device 30 is in scan mode (i.e. when the second signal SE is enabled) and the output of the shadow sequential element 310 assumes the value logical 0.

The state of the system latch ML 401 is reset asynchronously to the value logical 0 if the logic gate 403 is enabled. The system latch ML 401 is reset synchronously or asynchronously to the value logical 1 if the logic gate 403 is disabled and the device is in scan mode (i.e. when the signal SE is enabled). As a result, in scan mode, if the signal “reset_n” is disabled, the state of the system latch ML 401 is reset to the value logical 1 as soon as the state of the shadow latch ML 412 assumes the value logical 1, and the state of the system latch ML 401 is reset to the value logical 0 as soon as the state of the shadow latch ML 412 assumes the value logical 0. This property allows the transfer of the signal SI through the shadow latch ML 412 to the system sequential element 300 in scan mode.

In an embodiment of this type, the operation of asynchronous resetting to the value logical 0 of the system latch ML 401 takes priority over the operation of its asynchronous resetting to logical 1. Various implementations in the transistor can be used to apply this priority rule.

Independently from the value of the signal SE, the system sequential element 300 may be reset asynchronously to the value logical 0 as soon as the signal “reset_n” is disabled.

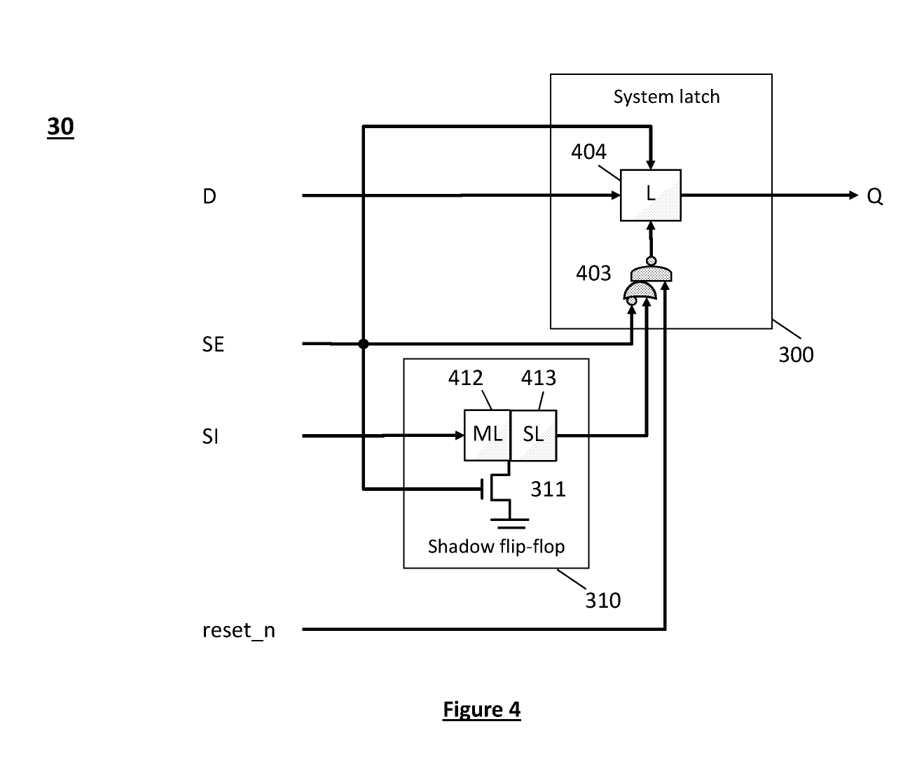

FIG. 4 shows a device 30 capable of being used as a scan latch with asynchronous resetting to the logical value 0 when the signal “reset_n” is enabled, according to a different embodiment of the invention.

In this embodiment of the invention, the system sequential element 300 includes a structure similar to FIG. 3. However, the system master latch 401 and the system slave latch 402 are replaced by a system latch 404, and the shadow sequential element 310 includes a shadow master latch 412 (also denoted ML) and a shadow slave latch 413 (also denoted SL), and may include a transistor 311 to disconnect the power supply of the latches ML 412 and SL 413 in capture mode.

The shadow latch ML 412 furthermore includes an input controlled by the signal SI and an output connected to the shadow latch SL 413. The shadow latch SL 413 furthermore includes an input controlled by the output of the latch ML 412 and an output connected to the output of the shadow sequential element 310.

The logic gate 403 shown in FIG. 4 is similar to the logic gate shown in FIG. 3 (also identified by the reference 403).

The system latch 404 furthermore includes three inputs and one output, including:
an input connected to the output of the logic gate 403,
an input controlled by the signal D,
an input controlled by the signal SE, and
an output which controls the signal Q.

The system latch 404 may include logic gates allowing the generation of a pulse from one of the (rising or falling) edges of the received clock signal (not shown in FIG. 4). Different methods for generating a pulse of this type can be used.

The state of the system latch 404 is reset asynchronously to the value logical 0 if the logic gate 403 is enabled. The system latch 404 is reset synchronously or asynchronously to the value logical 1 if the logic gate 403 is disabled and the device is in scan mode (when the signal SE is enabled). As a result, in scan mode, if the signal “reset_n” is disabled, the state of the system latch 404 is reset to the value logical 1 as soon as the state of the shadow latch SL 413 assumes the value logical 1, and the state of the system latch 404 is reset to the value logical 0 as soon as the state of the shadow latch SL 413 assumes the value logical 0. This property allows the transfer of the signal SI through the shadow latches ML 412 and SL 413 to the system sequential element 300 in scan mode.

In an embodiment of this type, the operation of asynchronous resetting to the value logical 0 of the system latch 404 takes priority over the operation of its asynchronous resetting to logical 1. Different implementations in the transistor can be used to apply this priority rule.

Independently from the value of the signal SE, the system sequential element 300 may be reset asynchronously to the value logical 0 as soon as the signal “reset_n” is enabled.

In other embodiments of the invention, a fifth asynchronous reset signal resetting to logical 1 (denoted “set”) can be used in parallel or in the absence of the asynchronous reset signal “reset_n” resetting to logical 0. In the description below, it will be assumed that the device 30 uses the signal “set” in the absence of the signal “reset_n”, by way of a non-limiting example.

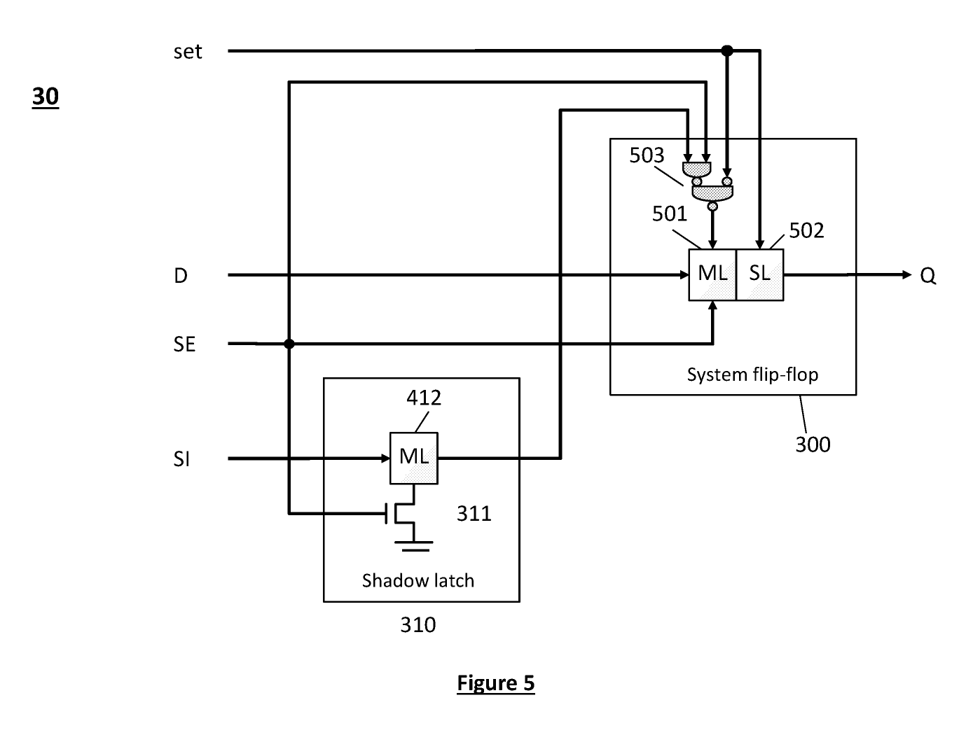

FIG. 5 shows a device 30 which can be used as a scan flip-flop with asynchronous resetting to logical 1 when a signal “set” is enabled, according to a different embodiment of the invention.

The system sequential element 300 shown in FIG. 5 includes a system master latch 501 (also denoted “ML”), a system slave latch 502 (also denoted “SL”) and a logic gate 503. The shadow sequential element 310 includes a master latch 412 (also referred to as a “shadow latch” and denoted “ML”) and a transistor 311 to disconnect the power supply of the shadow latch ML 512 in capture mode.

The shadow latch 412 furthermore includes an input controlled by the signal SI and an output connected to the output of the shadow sequential element 310.

The logic gate 503 includes:
an input controlled by the signal SE,
an input connected to the output of the shadow sequential element 310,
an input controlled by the signal “set”, and
an output connected to the latch ML 501.

The latch ML 501 furthermore includes three inputs and one output, including:
an input connected to the output of the logic gate 503,
an input controlled by the signal D,
an input controlled by the signal SE, and
an output connected to the latch SL 502.

The latch SL 502 furthermore includes two inputs and one output, including:
an input controlled by the latch ML 501,
an input controlled by the signal “set”,
an output which controls the signal Q.

The logic gate 503 is enabled, i.e. it has an impact on the state of the system sequential element 300, only if:
the asynchronous reset signal resetting to value logical 1 (“set”) is enabled, or
the device 30 is in scan mode (i.e. when the signal SE is enabled) and the output of the shadow sequential element (310) assumes the value logical 1.

The state of the system latch ML 501 is reset asynchronously to the value logical 1 if the logic gate 503 is enabled, and the system latch ML 501 is reset synchronously or asynchronously to the value logical 0 if the logic gate 503 is disabled and the device 30 is in scan mode. As a result, in scan mode, if the signal “set” is disabled, the state of the system latch ML 501 is reset to the value logical 0 as soon as the state of the shadow latch ML 412 assumes the value logical 0, and the state of the system latch ML 501 is reset to the value logical 1 as soon as the state of the shadow latch ML 412 assumes the value logical 1. This property allows the transfer of the signal SI through the shadow latch ML 412 to the system sequential element 300 in scan mode.

In an embodiment of this type, the operation of asynchronous resetting to the value logical 1 of the system latch ML 501 takes priority over the operation of its asynchronous resetting to logical 0. Various implementations in the transistor can be used to apply this priority rule.

Independently from the value of the signal SE, the system sequential element 300 may be reset asynchronously to the value logical 1 as soon as the signal “set” is enabled.

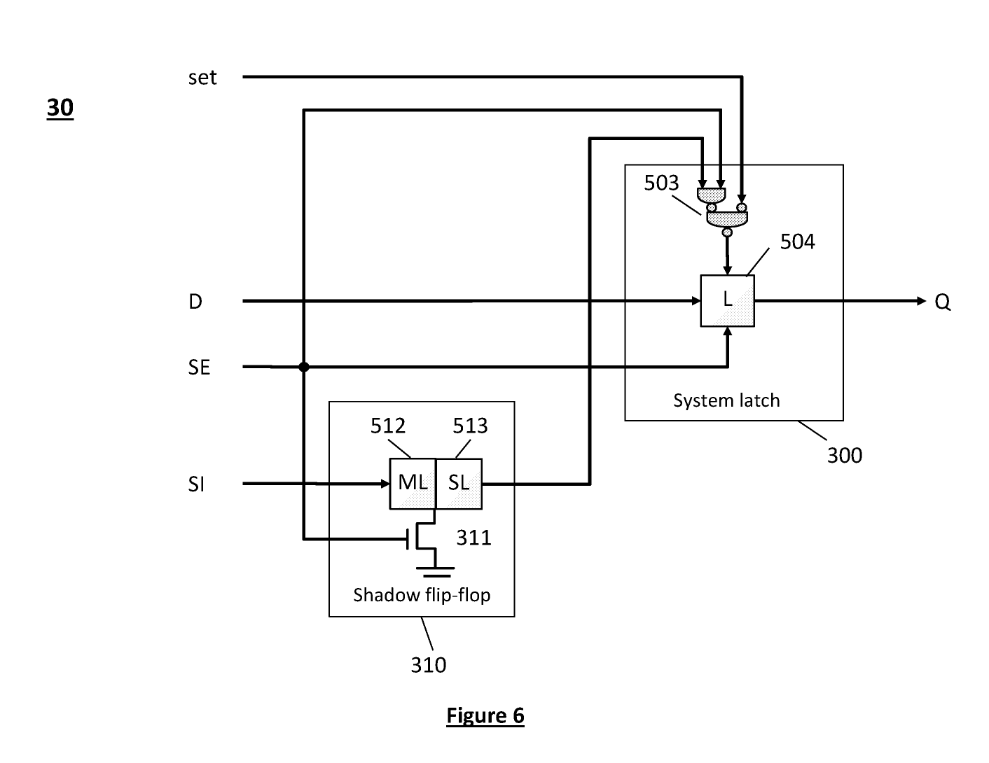

FIG. 6 shows a device 30 capable of being used as a scan latch with asynchronous resetting to the logical value 1 when the signal “set” is enabled, according to a different embodiment of the invention.

In this embodiment of the invention, the system sequential element 300 includes a structure similar to FIG. 5. However, the latches ML 501 and SL 502 are replaced by a system latch 504, and the shadow sequential element 310 includes shadow master latches 512 (ML) and a shadow slave latch 513 (SL) and may include a transistor 311 to disconnect the power supply of the latches ML 512 and SL 513 in capture mode.

The shadow latch ML 512 furthermore includes an input controlled by the signal SI and an output connected to the shadow latch SL 513. The latch SL 513 furthermore includes an input controlled by the latch ML 512 and an output connected to the output of the shadow sequential element 310.

The logic gate 503 shown in FIG. 6 is similar to the logic gate 503 shown in FIG. 5.

The system latch 504 furthermore includes three inputs and one output, including:
an input connected to the output of the logic gate 503,
an input controlled by the signal D,
an input controlled by the signal SE, and
an output which controls the signal Q.

The system latch 504 may include logic gates allowing the generation of a pulse from one of the (rising or falling) edges of the received clock signal (not shown in FIG. 6). Different methods for generating a pulse of this type can be used.

The state of the system latch 504 is reset asynchronously to the value logical 1 if the logic gate 503 is enabled, and the system latch 504 is reset synchronously or asynchronously to the value logical 0 if the logic gate 503 is disabled and the device 30 is in scan mode. Consequently, in scan mode, if the signal “set” is disabled, the state of the system latch 504 is reset to the value logical 0 as soon as the state of the shadow latch SL 513 assumes the value logical 0, and the state of the system latch 504 is reset to the value logical 1 as soon as the state of the shadow latch SL 513 assumes the value logical 1. This property allows the transfer of the signal SI through the shadow latches ML 512 and SL 513 to the system sequential element 300 in scan mode.

In this embodiment, the operation of asynchronous resetting to the value logical 1 of the system latch 504 takes priority over the operation of its asynchronous resetting to logical 0. A priority rule of this type can be applied by means of various implementations in the transistor.

Independently from the value of the signal SE, the system sequential element 300 may be reset asynchronously to the value logical 1 as soon as the signal “set” is enabled.

The device 30 shown in FIGS. 3, 4, 5, 6 may include any type of combinations of transistors or logic gates capable of implementing the preceding conditions. Nor is the device limited to particular types of transistors, gates or interconnections between these elements in order to implement the conditions above.

Generally speaking, the invention is not limited to the embodiments described above by way of non-limiting examples. It encompasses all the alternative embodiments that can be envisaged by the person skilled in the art. In particular, it is not limited to a number or type or particular arrangement of gates and transistors in order to implement the conditions above. Furthermore, it can be applied alternatively to system flip-flops which change their state on the falling edge of the clock signal or to system latches which become transparent on the low level of the clock signal or to different encodings of the capture and scan modes.

Furthermore, although the embodiments of the invention above have been described on the basis of certain definitions of the concepts of action/disablement of the signals, the person skilled in the art will readily understand that the invention also applies to the embodiments where the concepts of enablement/disablement of the signals (in particular SE, reset_n, set) are defined with different logical values.

1. A scan sequential element device for an integrated circuit, the device receiving three input signals and at least one clock signal as input, and including an output, wherein the device includes:
a system sequential element including an input controlled by a first input signal of the device, an input controlled by a second input signal of the device, and an input controlled by one of said clock signals received as input by the device, and
a shadow sequential element including an input controlled by the third input signal of the device, an input controlled by the second input signal of the device, and an input controlled by one of said clock signals received as input by the device,
and wherein the device is configured in such a way that the first input signal is propagated to the output of the device through the system sequential element when the second input signal is disabled, and the third input signal is propagated to the output of the device through the shadow sequential element and the system sequential element when the second input signal is enabled, the propagation of the third input signal of the shadow sequential element to the system sequential element being implemented asynchronously.

2. The device as claimed in claim 1, wherein the shadow sequential element is configured to be disconnected from the power supply when the second signal is disabled.

3. The device as claimed in claim 2, wherein the shadow sequential element includes at least one transistor connected to the third input controlled by the second signal, said transistor being configured to disconnect the power supply of the shadow sequential element when the second input signal is disabled.

4. The device as claimed in claim 1, wherein the system sequential element is a sequential element in the form of either a flip-flop other than a scan flip-flop or a latch, whereas the shadow sequential element is a sequential element in the form of either a scan flip-flop, a flip-flop other than a scan flip-flop, or a latch.

5. The device as claimed in claim 1, wherein the device can be connected at its input to an asynchronous reset signal resetting to the value logical 0 and/or to an asynchronous reset signal resetting to the value logical 1, and wherein the device is configured to form a scan flip-flop with asynchronous resetting to the value logical 0 and/or the value logical 1.

6. The device as claimed in claim 5, wherein the system sequential element includes a system master latch, a system slave latch, and a logic gate, and wherein the shadow sequential element includes a shadow latch receiving the third signal as input and being connected at its output to the output of the shadow sequential element, said logic gate receiving as input the second signal, the output of the shadow sequential element and the asynchronous reset signal resetting to the value logical 0, and being connected at its output to the system master latch the system master latch furthermore receiving the first input signal of the device and the second input signal of the device as input and being connected at its output to the system slave latch, the system slave latch being connected at its input to the system master latch and to the asynchronous reset signal resetting to logical 0 and being connected at its output to the output of the device.

7. The device as claimed in claim 5, wherein the system sequential element includes a system latch and a logic gate, and wherein the shadow sequential element includes a shadow master latch receiving the third signal as input, and a shadow slave latch being connected at its output to the output of the shadow sequential element, said logic gate receiving as input the second signal, the output of the shadow sequential element and the asynchronous reset signal resetting to the value logical 0, and being connected at its output to the system latch, the system latch furthermore receiving the first input signal of the device and the second input signal of the device as input and being connected at its output to the output of the device.

8. The device as claimed in claim 6, wherein the state of the system latch is reset asynchronously to the value logical 0 if the logic gate is enabled, and wherein the system latch is reset synchronously or asynchronously to the value logical 1 if the logic gate is disabled and if the device is in scan mode, the device being in scan mode when the second signal is enabled.

9. The device as claimed in claim 8, wherein the logic gate is enabled only if:
the asynchronous reset signal resetting to the value logical 0 is enabled, or
the device is in scan mode and the output of the shadow sequential element assumes the value logical 0.

10. The device as claimed in claim 5, wherein the system sequential element includes a system master latch, a system slave latch, and a logic gate, and in that the shadow sequential element includes a shadow latch receiving the third signal as input and being connected at its output to the output of the shadow sequential element, said logic gate receiving as input the second signal, the output of the shadow sequential element and the asynchronous reset signal resetting to logical 1, and being connected at its output to the system master latch, the system master latch furthermore receiving the first input signal of the device and the second input signal of the device as input and being connected at its output to the system slave latch, the system slave latch being connected at its input to the system latch and to the asynchronous reset signal resetting to logical 1 and being connected at its output to the output of the device.

11. The device as claimed in claim 5, wherein the system sequential element includes a system latch and a logic gate, and wherein the shadow sequential element includes a shadow master latch receiving the third signal as input, and a shadow slave latch being connected at its output to the output of the shadow sequential element, said logic gate receiving as input the second signal, the output of the shadow sequential element and the asynchronous reset signal resetting to the value logical 1, and being connected at its output to the system latch the system latch furthermore receiving the first input signal of the device and the second input signal of the device as input and being connected at its output to the output of the device.

12. The device as claimed in claim 10, wherein the state of the system latch is reset asynchronously to the value logical 1 if the logic gate is enabled, and wherein the system latch is reset synchronously or asynchronously to the value logical 0 if the logic gate is disabled and if the device is in scan mode, the device being in scan mode when the second signal is enabled.

13. The device as claimed in claim 12, wherein the logic gate is enabled only if:
the asynchronous reset signal resetting to the value logical 1 is enabled, or
the device is in scan mode and the output of the shadow sequential element assumes the value logical 1.
